(19) United States
(12) Patent Application Publication
(10) Pub. No.: US 2026/0123152 A1
(43) Pub. Date: Apr. 30, 2026

(54) PACKAGE STRUCTURE

(71) Applicant: Lextar Electronics Corporation, Hsinchu City (TW)

(72) Inventors: Shiou-Yi KUO, Hsinchu City (TW); Jian-Chin LIANG, Hsinchu City (TW)

(21) Appl. No.: 19/366,747

(22) Filed: Oct. 23, 2025

(30) Foreign Application Priority Data
Oct. 25, 2024 (TW) 113140728

(51) Int. Cl. H10H 29/80; H01L 25/075; H10H 20/857; H10H 29/24; H10H 29/85; H10H 29/853

(52) U.S. Cl. CPC H10H 29/8421; H10H 20/857; H10H 29/24; H10H 29/8508; H10H 29/853; H10W 90/00

(57) ABSTRACT

A packaging structure is provided. The packaging structure includes a dielectric layer, a redistribution layer, a plurality of light-emitting elements, a photodegradation prevention layer, and a cover layer. The redistribution layer is disposed on the dielectric layer. The plurality of light-emitting elements is disposed on the redistribution layer and electrically connected to the redistribution layer. The photodegradation prevention layer is disposed on the dielectric layer and surrounds the plurality of light-emitting elements. The cover layer is disposed on the plurality of light-emitting elements and the photodegradation prevention layer. The area of the photodegradation prevention layer accounts for at least 50% of the area of the cover layer.

### CROSS REFERENCE TO RELATED APPLICATIONS

This application claims priority of Taiwan Patent Application No. TW 113140728, filed on Oct. 25, 2024, the entirety of which is incorporated by reference herein.

### TECHNICAL FIELD

The present disclosure relate to a packaging structure, and, in particular, it relates to a packaging structure including a photodegradation prevention layer.

### BACKGROUND

As the size of packaging structures becomes smaller, existing packaging structures often have problems such as insufficient bonding reliability and electrical failure. Therefore, it is limited in applications requiring high light-emitting efficiency and high brightness.

Therefore, although existing packaging structures have gradually met their intended uses, they still do not fully meet the requirements in all aspects. Therefore, there are still some problems to be overcome regarding the packaging structure.

### SUMMARY

The packaging structure of the present disclosure may include a photodegradation prevention layer disposed on the dielectric layer to prevent the light emitted by the light emitting element from damaging various elements in the package structure, such as the dielectric layer, and causing degradation of the various elements. For example, the photodegradation prevention layer may include metal or a Bragg reflector to effectively prevent the elements disposed under the photodegradation prevention layer from being damaged by the light emitted by the light-emitting element. Therefore, the packaging structure of the present disclosure can improve light-emitting efficiency, improve bonding reliability, and/or avoid electrical failure.

In some embodiments, a packaging structure is provided. The packaging structure includes a dielectric layer, a redistribution layer, a plurality of light-emitting elements, a photodegradation prevention layer, and a cover layer. The redistribution layer is disposed on the dielectric layer. The plurality of light-emitting elements is disposed on the redistribution layer and electrically connected to the redistribution layer.

The photodegradation prevention layer is disposed on the dielectric layer and surrounds the plurality of light-emitting elements. The cover layer is disposed on the plurality of light-emitting elements and the photodegradation prevention layer. The area of the photodegradation prevention layer accounts for at least 50% of the area of the cover layer.

The packaging structure of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 is a schematic top view of a packaging structure 1 according to some embodiments of the present disclosure.

FIG. 2 and FIG. 3 are schematic cross-sectional views of the packaging structure 1 according to some embodiments of the present disclosure, respectively.

FIG. 4 is a schematic top view of a package structure 2 according to some embodiments of the present disclosure.

FIG. 5 and FIG. 6 are schematic cross-sectional views of the packaging structure 2 according to some embodiments of the present disclosure, respectively.

FIG. 7 is a schematic top view of a packaging structure 3 according to some embodiments of the present disclosure.

FIG. 8 and FIG. 9 are schematic cross-sectional views of the packaging structure 3 according to some embodiments of the present disclosure, respectively.

FIG. 10 is a schematic top view of a packaging structure 4 according to some embodiments of the present disclosure.

FIG. 11 and FIG. 12 are schematic cross-sectional views of the packaging structure 4 according to some embodiments of the present disclosure, respectively.

FIG. 13 is a schematic top view of a packaging structure 5 according to some embodiments of the present disclosure.

FIG. 14 and FIG. 15 are schematic cross-sectional views of the packaging structure 5 according to some embodiments of the present disclosure, respectively.

FIG. 16 is a schematic cross-sectional view of a display device 6 according to some embodiments of the present disclosure.

FIG. 17 is a schematic top view of a spliced display device 7 according to some embodiments of the present disclosure.

### DETAILED DESCRIPTION

Packaging structures of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure. Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact. In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The term “between a first value and a second value” or “a first value ˜ a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For ease of description, hereinafter, the X-axis represents a first direction D1 (width direction), the Y-axis represents a second direction D2 (length direction), and the Z-axis represents a third direction D3 (thickness/depth direction). In some embodiments, the schematic top views of the present disclosure are schematic top views observing the XY plane, and the schematic cross-sectional views of the present disclosure are schematic cross-sectional views observing the XZ plane. In some embodiments, the third direction D3 may be a normal direction of the light-emitting element. In some embodiments, the terms “a distance between a first element and a second element” means that the distance is between a first boundary of the first element and a second boundary of the second element, wherein the second boundary is the boundary closest to the first element.

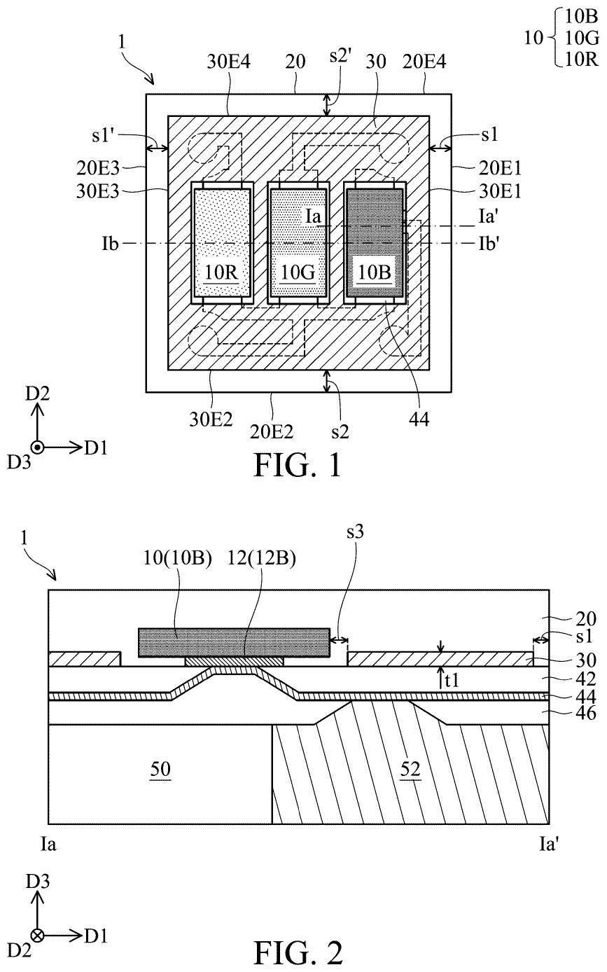

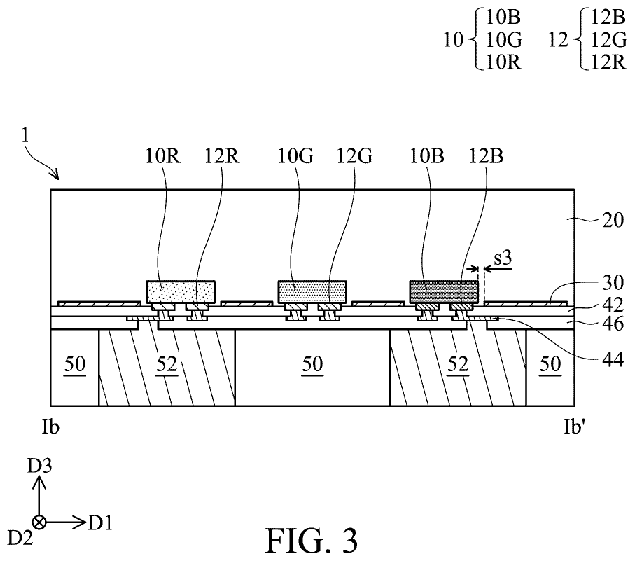

Referring to FIG. 1, it is a schematic top view of a packaging structure 1 according to some embodiments of the present disclosure. Meanwhile, referring to FIGS. 2 and 3, they are schematic cross-sectional views of the packaging structure 1 according to some embodiments of the present disclosure. FIG. 2 shows a schematic cross-sectional view taken along line segment Ia-Ia′ in FIG. 1, and FIG. 3 shows a schematic cross-sectional view taken along line segment Ib-Ib′ in FIG. 1. As shown in FIGS. 1 to 3, in some embodiments, the packaging structure 1 may include a dielectric layer 46, a redistribution layer 44, a plurality of light-emitting elements 10, a photodegradation prevention layer 30, and a cover layer 20.

As shown in FIGS. 1 to 3, in some embodiments, the dielectric layer 46 may include an oxide such as silicon oxide, a nitride such as silicon nitride, an oxynitride such as silicon oxynitride, a polymer, a resin, the like, or a combination thereof, but the present disclosure is not limited thereto. In some embodiments, the polymer may include polyimide (PI), polybenzoxazole (PBO), benzocyclobutene (BCB), the like, or a combination thereof, but the present disclosure is not limited thereto. For example, the dielectric layer 46 may include polybenzoxazole.

As shown in FIGS. 1 to 3, in some embodiments, the redistribution layer 44 may be disposed on the dielectric layer 46. In some embodiments, the redistribution layer 44 may include a conductive material. In some embodiments, the conductive material may include a metal, a conductive metal oxide, a conductive metal nitride, the like, or a combination thereof, but the present disclosure is not limited thereto. For example, the metal may include tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), titanium (Ti), magnesium (Mg), zinc (Zn), alloys thereof, compounds thereof, or a combination thereof, but the present disclosure is not limited thereto. For example, the conductive metal oxide may be a transparent conductive oxide (TCO). For example, the transparent conductive oxide may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), the like, or a combination thereof, but the present disclosure is not limited thereto. For example, the conductive metal nitride may include TIN, WN, TaN, the like, or a combination thereof, but the present disclosure is not limited thereto.

As shown in FIGS. 1 to 3, in some embodiments, the plurality of light-emitting elements 10 may be disposed on the redistribution layer 44, and the plurality of light-emitting elements 10 may be electrically connected to the redistribution layer 44. In some embodiments, in the first direction D1, the light-emitting elements 10 may be arranged spaced apart from each other. In some embodiments, in the third direction D3, the light-emitting element 10 may emit light upward. In some embodiments, the light-emitting element 10 may be a light-emitting diode (LED), a mini light-emitting diode (mini LED), a micro light-emitting diode (micro LED), the like, or a combination thereof, but the present disclosure is not limited thereto.

In some embodiments, the light-emitting element 10 may emit a red light, a green light, a blue light, an ultraviolet light (UV light) or light of other suitable wavelengths. In some embodiments, the number of the light-emitting elements 10 in the packaging structure 1 may be 1 to 100. For ease of description, three light-emitting elements 10 are shown in FIGS. 1 to 3 and subsequent drawings, but the present disclosure is not limited thereto.

In some embodiments, the light-emitting elements 10 may include a red light-emitting element 10R emitting the red light, a green light-emitting element 10G emitting the green light, and a blue light-emitting element 10B emitting the blue light. In some embodiments, the green light-emitting element 10G may be disposed between the red light-emitting element 10R and the blue light-emitting element 10B. In some embodiments, the light-emitting element 10 may include a growth substrate (not shown), a semiconductor stack (not shown), an insulating layer (not shown), a functional layer such as a reflective layer (not shown), and two bonding pads 12. In some embodiments, the semiconductor stack may include a first semiconductor layer (not shown), a light-emitting layer (not shown), and a second semiconductor layer (not shown) stacked in sequence, and the first semiconductor layer and the second semiconductor layer have different conductivity types. In some embodiments, the bonding pad 12 may be electrically connected to the semiconductor stack. In some embodiments, the bonding pad 12 may include the aforementioned conductive material. In some embodiments, the light-emitting element 10 (for example, the red light-emitting element 10R, the green light-emitting element 10G, and the blue light-emitting element 10B) may be electrically connected to the redistribution layer 44 via the bonding pads 12 (for example, bonding pads 12R, bonding pads 12G, and bonding pads 12B). In some embodiments, the light-emitting element 10 may be devoid of a growth substrate (not shown), for example, the light-emitting element 10 may include the semiconductor stack but does not include a growth substrate on which the semiconductor stack is grown. In some embodiments, the light-emitting surfaces of the red light-emitting element 10R, the blue light-emitting element 10B, and the green light-emitting element 10G have a roughened structure. In some embodiments, the light-emitting surface of the blue light-emitting element 10B or the green light-emitting element 10G has a uniform roughened structure. The blue light-emitting element 10B and the green light-emitting element 10G have upper surfaces with periodically arranged concave-convex patterns. For example, the blue light-emitting element 10B and the green light-emitting element 10G are devoid of a growth substrate such as a patterned sapphire substrate (PSS), and their light-emitting surfaces have periodically arranged concave-convex patterns generated by laser lifting-off the patterned sapphire substrate. Specifically, the aforementioned concavo-convex patterns can be used to enhance light extraction and adjust the angle of direction of the blue light-emitting element 10B and the green light-emitting element 10G. In some embodiments, the light-emitting surface of the red light-emitting element 10R has a non-uniform roughened structure (for example, non-uniform patterns). In some embodiments, a chemical etching may be used to produce the non-uniform roughened structure on the light-emitting surface of the red light-emitting element 10R.

As shown in FIGS. 1 to 3, in some embodiments, the photodegradation prevention layer 30 may be disposed on the dielectric layer 46, and the photodegradation prevention layer 30 may surround the plurality of light-emitting elements 10 to prevent the light emitted by the light-emitting elements 10 from irradiating the dielectric layer 46 and an intermediate layer 42 below the photodegradation prevention layer 30. In some embodiments, the photodegradation prevention layer 30 may surround the bottom of the light-emitting element 10. In some embodiments, the photodegradation prevention layer 30 may surround the bonding pads 12 of the light-emitting element 10. That is, the photodegradation prevention layer 30 may cover at least a portion of the side surface or all of the side surface of the bonding pad 12. In some embodiments, in the third direction D3, the photodegradation prevention layer 30 may at least partially overlap the redistribution layer 44.

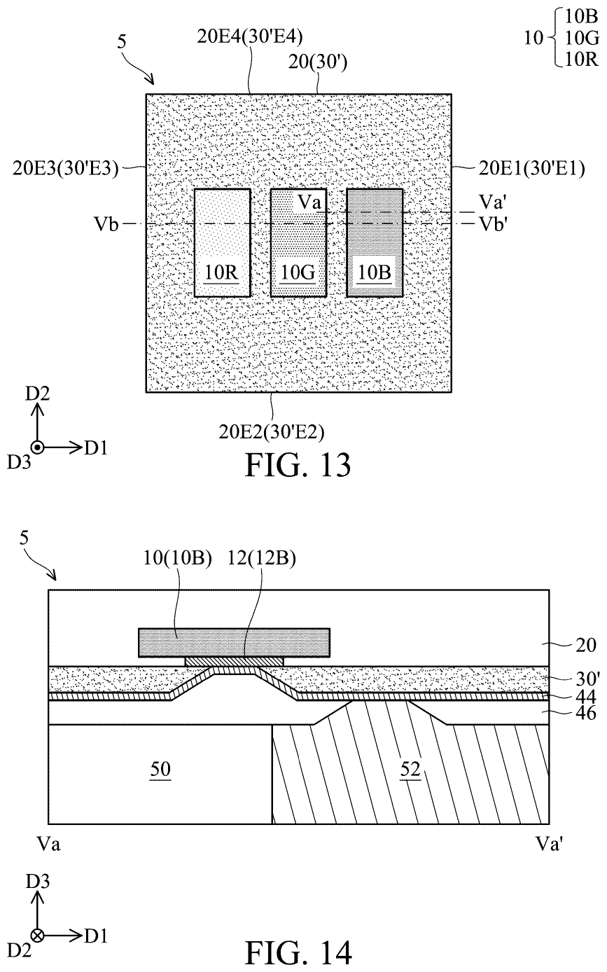

In some embodiments, the photodegradation prevention layer 30 may include a metal, but the present disclosure is not limited thereto. For example, the metal may include tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), titanium (Ti), magnesium (Mg), zinc (Zn), alloys thereof, compounds thereof, or a combination thereof, but the present disclosure is not limited thereto. In some embodiments, the material of the photodegradation prevention layer 30 may be the same as or different from the material of the redistribution layer 44. In other embodiments, the photodegradation preventing layer (for example, the photodegradation prevention layer 30′ shown in FIGS. 13 to 15) may include a Bragg reflector.

As shown in FIGS. 1 to 3, in some embodiments, in the normal direction (third direction D3) of the light-emitting element 10, a top surface of the photodegradation prevention layer 30 may be flush with or lower than a top surface of the light-emitting element 10. Accordingly, the photodegradation prevention layer 30 can be prevented from affecting the visual effect of the packaging structure 1. For example, the photodegradation prevention layer 30 can be prevented from reflecting light and causing problems such as bright spots and bright lines. In some embodiments, in the third direction D3, the photodegradation prevention layer 30 may have a thickness t1. In some embodiments, in the third direction D3, the thickness t1 of the photodegradation prevention layer 30 may be less than or equal to 5000 angstroms (Å). For example, the thickness t1 of the photodegradation prevention layer 30 may be 5000 angstroms, 4500 angstroms, 4000 angstroms, 3500 angstroms, 3000 angstroms, 2500 angstroms, 2000 angstroms, 1000 angstroms, or any value or any range of values between the aforementioned values, but the present disclosure is not limited thereto.

As shown in FIGS. 1 to 3, in some embodiments, the cover layer 20 may be disposed on the plurality of light-emitting elements 10 and the photodegradation prevention layer 30. In some embodiments, the cover layer 20 may cover the top surface and a side surface of the light-emitting element 10 and the top surface and a side surface of the photodegradation prevention layer 30. In some embodiments, the cover layer 20 may include an oxide such as silicon oxide, a nitride such as silicon nitride, an oxynitride such as silicon oxynitride, a polymer, a resin, the like, or a combination thereof, but the present disclosure is not limited thereto. For example, the cover layer 20 may include hybrid-silicone. In some embodiments, the light emitted by the light-emitting element 10 is transmitted sequentially from the light-emitting surface and the cover layer 20 all the way outward (for example, toward the third direction D3). Therefore, the light transmittance (for example, the light transmittance in a range of the visible light) of the cover layer 20 may be greater than or equal to 80% to provide a better display effect, but the present disclosure is not limited thereto. For example, the light transmittance of the cover layer 20 may be 80%, 85%, 90%, 95%, 100% or any range of values between the aforementioned values.

As shown in FIG. 1, in some embodiments, in a top view, an area of the photodegradation prevention layer 30 may account for (occupy) at least 50% of an area of the cover layer 20. For example, the area of the photodegradation prevention layer 30 may be 50%, 55%, 60%, 65%, 70%, 75%, 80%, 85%, 90%, 95%, 97%, 99%, 100% of the area of the cover layer 20, or any value or any range of values between the aforementioned values, but the present disclosure is not limited thereto. In some embodiments, the area of the cover layer 20 may be substantially equal to the area of the packaging structure 1. In some embodiments, the area of the photodegradation prevention layer 30 may account for at least 50% of the area of the packaging structure 1. Accordingly, since the photodegradation prevention layer 30 has a sufficient top-view area, the photodegradation prevention layer 30 can effectively prevent the light emitted by the light-emitting element 10 in the packaging structure 1 from damaging other elements in the packaging structure 1. For example, the photodegradation prevention layer 30 can prevent the dielectric layer 46 and the intermediate layer (for example, the intermediate layer 42) from being degraded after being irradiated by the light emitted from the light-emitting element 10, thereby increasing the reliability of the packaging structure 1.

As shown in FIG. 1, in some embodiments, in a top view, in the first direction D1, a distance s1 between an edge 30E1 of the photodegradation prevention layer 30 and an edge 20E1 of the cover layer 20 may be less than 20 um. In some embodiments, the distance s1 may be greater than or equal to 0 (zero). In some embodiments, in a top view, in the first direction D1, a distance s1′ between an edge 30E3 of the photodegradation prevention layer 30 and an edge 20E3 of the cover layer 20 may be less than 20 um. In some embodiments, the distance s1′ may be greater than or equal to 0. In some embodiments, in a top view, in the second direction D2, a distance s2 between an edge 30E2 of the photodegradation prevention layer 30 and an edge 20E2 of the cover layer 20 may be less than 20 um. In some embodiments, the distance s2 may be greater than or equal to 0. In some embodiments, in a top view, in the second direction D2, a distance s2′ between an edge 30E4 of the photodegradation prevention layer 30 and an edge 20E4 of the cover layer 20 may be less than 20 um. In some embodiments, the distance s2′ may be greater than or equal to 0. For example, each of the distances s1, s1′, s2, s2′ may be 0, 1 um, 2 um, 5 um, 10 um, 15 um, 19 um, 19.9 um, or any value or any range of values between the aforementioned values, but the present disclosure is not limited thereto.

In some embodiments, when the photodegradation prevention layer 30 may include a metal, each of the distances s1, s1′, s2, s2′ may be greater than 0 to improve the process margin (process window) of the cutting process and the reliability of the packaging structure 1. The packaging structure 1 can be obtained by performing a cutting process. In some embodiments, when the photodegradation prevention layer 30 may include a metal, each of the distances s1, s1′, s2, s2′ may be greater than or equal to 10 um to correspond to the blade width or laser beam diameter of the cutting process, thereby further improving the process margin of the cutting process and the reliability of the packaging structure 1.

In other embodiments (for example, the packaging structure 5 shown in FIGS. 13 to 15), when the photodegradation prevention layer 30′ may include a Bragg reflector, at least one or each of the distances s1, s1′, s2, s2′ may be equal to 0 to increase the area of the Bragg reflector and fully avoid the light emitted by the light-emitting element 10 from damaging other elements in the packaging structure, thereby improving the reliability of the packaging structure.

As shown in FIG. 1 and FIG. 2, in some embodiments, a patterned metal layer may be formed on the cover layer 20, wherein the patterned metal layer may serve as the photodegradation prevention layer 30. Next, another patterned metal layer may be formed on the photodegradation prevention layer 30, wherein the other patterned metal layer may serve as the redistribution layer 44. Accordingly, the photodegradation prevention layer 30 and the redistribution layer 44 can be formed at the same time.

As shown in FIG. 2 and FIG. 3, in some embodiments, the photodegradation prevention layer 30 may be in direct contact with the cover layer 20. In some embodiments, a bottom surface of the photodegradation prevention layer 30 may be flush with a bottom surface of the cover layer 20 (that is, the bottom surface of the photodegradation prevention layer 30 is coplanar with the bottom surface of the cover layer 20). In some embodiments, in the third direction D3, the top surface of the photodegradation prevention layer 30 may be higher than a top surface of the redistribution layer 44. In some embodiments, the redistribution layer 44 may be spaced apart from the cover layer 20 by a distance. In other words, the redistribution layer 44 may not directly contact the cover layer 20. In some embodiments, the redistribution layer 44 may be physically separated from the cover layer 20. In some embodiments, the intermediate layer 42 may be disposed between the redistribution layer 44 and the cover layer 20.

As shown in FIGS. 2 and 3, in some embodiments, in the first direction D1, the photodegradation prevention layer 30 may be spaced apart from the light-emitting element 10 closest to the photodegradation prevention layer 30 among the plurality of light-emitting elements 10 by a distance s3. For example, in the first direction D1, the photodegradation prevention layer 30 may be spaced apart from the blue light-emitting element 10B by the distance s3. In some embodiments, the distance s3 may be less than or equal to 10 um. In some embodiments, the distance s3 may be greater than or equal to 0. For example, the distance s3 may be 0 um, 1 um, 2 um, 3 um, 4 um, 5 um, 6 um, 7 um, 8 um, 9 um, 10 um, or any value or any range of values between the aforementioned values, but the present disclosure is not limited thereto. In some embodiments, the distance s3 may be greater than or equal to 5 um. Accordingly, the area of the photodegradation prevention layer 30 can be increased while maintaining the process margin of the photodegradation prevention layer 30, thereby improving the blocking effect of the photodegradation prevention layer 30 on the light emitted from the light-emitting element 10.

As shown in FIGS. 2 and 3, in some embodiments, the packaging structure 1 may further include the intermediate layer 42. In some embodiments, the intermediate layer 42 may be disposed on the redistribution layer 44. In some embodiments, the intermediate layer 42 may be disposed between the dielectric layer 46 and the photodegradation prevention layer 30. In some embodiments, the light-emitting element 10 may be in direct contact with the intermediate layer 42 and the redistribution layer 44. In some embodiments, the material of the intermediate layer 42 may be the same as or different from the material of the dielectric layer 46. For example, the intermediate layer 42 may include polybenzoxazole. In some embodiments, the photodegradation prevention layer 30 may be disposed on the intermediate layer 42. In some embodiments, the cover layer 20 may be in direct contact with the light-emitting element 10, the photodegradation prevention layer 30, and the intermediate layer 42.

As shown in FIG. 2 and FIG. 3, in some embodiments, the packaging structure 1 may further include a filling material layer 50 and metal pillars 52. In some embodiments, the dielectric layer 46 may be disposed between the redistribution layer 44 and the filling material layer 50. In some embodiments, the metal pillars 52 may be disposed in the filling material layer 50, and the metal pillars 52 may be electrically connected to the redistribution layer 44. In other words, since the light-emitting element 10, the redistribution layer 44, and the metal pillars 52 can be electrically connected to each other, the packaging structure 1 can be electrically connected to an external element through the metal pillars 52. In some embodiments, the filling material layer 50 may include a molding material. In some embodiments, the molding material may include epoxy, silicone, the like, or a combination thereof, but the present disclosure is not limited thereto. In some embodiments, the metal pillars 52 may include the conductive material. The metal pillars 52 can significantly increase the thickness and volume of the metal layer in the packaging structure 1 so as to improve current distribution, heat dissipation of the light-emitting element 10 such as LED, stress release, pressure buffering during subsequent die bonding, and element life. In some embodiments, the metal pillars 52 may be formed by an electroplating process, a evaporation process, a screen printing process, a vacuum spraying process, the like, or a combination thereof. In some embodiments, in the third direction D3, a thickness of the metal pillars 52 may be between 5 um and 100 um. For example, the material of the metal pillars 52 may include a metal, a metal alloy, a metal compound, or a combination thereof. For example, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), titanium (Ti), magnesium (Mg), zinc (Zn), germanium (Ge), or an alloy thereof. For example, the metal compound may be tantalum nitride (TaN), titanium nitride (TiN), tungsten silicide (WSi₂), indium tin oxide (ITO), and the like.

Accordingly, the redistribution layer 44 and the metal pillars 52 in the packaging structure 1 can be used together as an extended electrode of the light-emitting element 10 to improve the light-emitting efficiency, improve the bonding reliability, and/or avoid electrical failure. Specifically, the alignment during bonding processes such as a fusion bonding is difficult to align, and results in reduced light-emitting efficiency of the light-emitting element 10, insufficient bonding reliability, and even electrical failure of the light-emitting element 10. In addition, since bonding processes such as fusion bonding require precise alignment, the process margin is also limited. Therefore, based on the present disclosure, the use of the redistribution layer 44 and the metal pillars 52 as the extended electrodes of the packaging structure 1 can effectively avoid the aforementioned problems existing in the pad-to-pad (point-to-point) bonding structure.

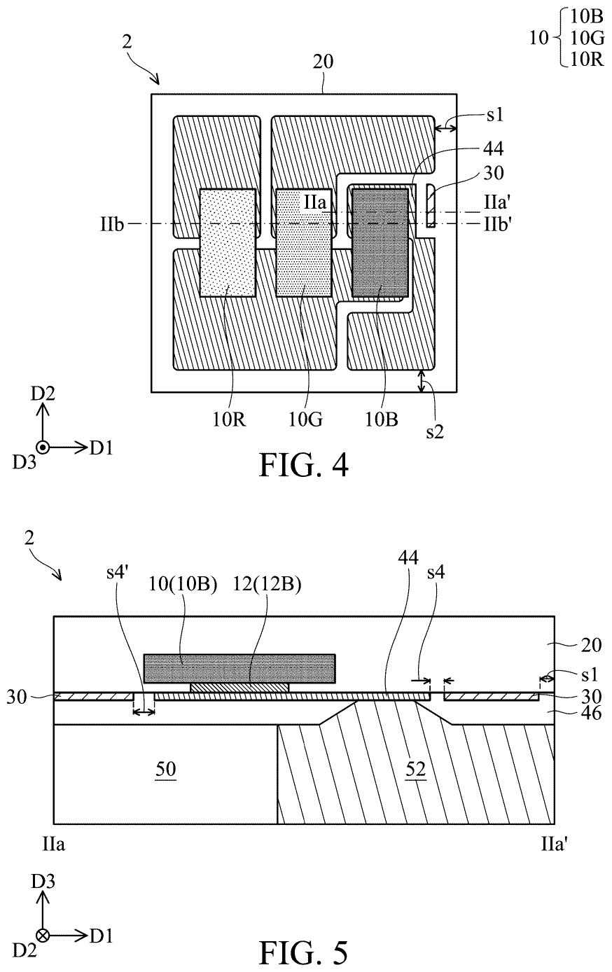

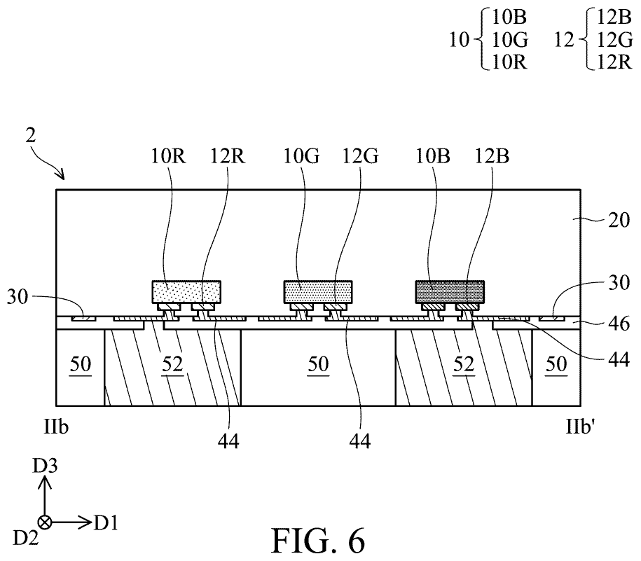

Referring to FIG. 4, it is a schematic top view of a packaging structure 2 according to some embodiments of the present disclosure. Referring to FIGS. 5 and 6, they are schematic cross-sectional views of the packaging structure 2 according to some embodiments of the present disclosure. Wherein, FIG. 5 shows a schematic cross-sectional view taken along line segment IIa-IIa′ in FIG. 4, and FIG. 6 shows a schematic cross-sectional view taken along line segment IIb-IIb′ in FIG. 4.

As shown in FIG. 4, in some embodiments, a patterned metal layer may be formed on the cover layer 20, wherein a portion of the patterned metal layer may serve as the redistribution layer 44, and the remaining portion of the patterned metal layer may serve as the photodegradation prevention layer 30. Accordingly, the process of forming the packaging structure 2 can be simplified, and the photodegradation prevention layer 30 and the redistribution layer 44 can be formed at the same time.

As shown in FIG. 4, in some embodiments, in the third direction D3, the photodegradation prevention layer 30 may not overlap the redistribution layer 44. As shown in FIGS. 5 and 6, in some embodiments, the photodegradation prevention layer 30 may be in direct contact with the cover layer 20, and the redistribution layer 44 may be in direct contact with the cover layer 20. In some embodiments, the top surface of the photodegradation prevention layer 30 may be in direct contact with the bottom surface of the cover layer 20, and the top surface of the redistribution layer 44 may be in direct contact with the bottom surface of the cover layer 20. In some embodiments, in the third direction D3, the top surface of the photodegradation prevention layer 30 may be flush with the top surface of the redistribution layer 44. In some embodiments, the photodegradation prevention layer 30 may surround the redistribution layer 44. In some embodiments, the photodegradation prevention layer 30 may be physically separated from the redistribution layer 44. In other words, in the first direction D1 and/or the second direction D2, the photodegradation prevention layer 30 may be spaced apart from the redistribution layer 44 by a distance s4 or s4′. In some embodiments, each of distances s4 and s4′ may be greater than 0.

As shown in FIGS. 5 and 6, in some embodiments, the photodegradation prevention layer 30 and the redistribution layer 44 may be disposed on the same layer. That is, the photodegradation prevention layer 30 and the redistribution layer 44 may be together disposed on the dielectric layer 46. In some embodiments, the bottom surface of the photodegradation prevention layer 30 may be flush with a bottom surface of the redistribution layer 44. In some embodiments, the photodegradation prevention layer 30 and the redistribution layer 44 may be formed by the same process step or by different process steps. For example, the photodegradation prevention layer 30 and the redistribution layer 44 may be formed by the same process step, and the photodegradation prevention layer 30 and the redistribution layer 44 may include the same material. In some embodiments, the intermediate layer 42 may be omitted in the packaging structure 2 to reduce the overall thickness of the packaging structure 2 and/or simplify the process. In some embodiments, a portion of the dielectric layer 46 may be exposed from the distances s4 and s4′ between the photodegradation prevention layer 30 and the redistribution layer 44. In some embodiments, a portion of the dielectric layer 46 may be exposed from the distance s1 between an edge of the photodegradation prevention layer 30 and an edge of the cover layer 20.

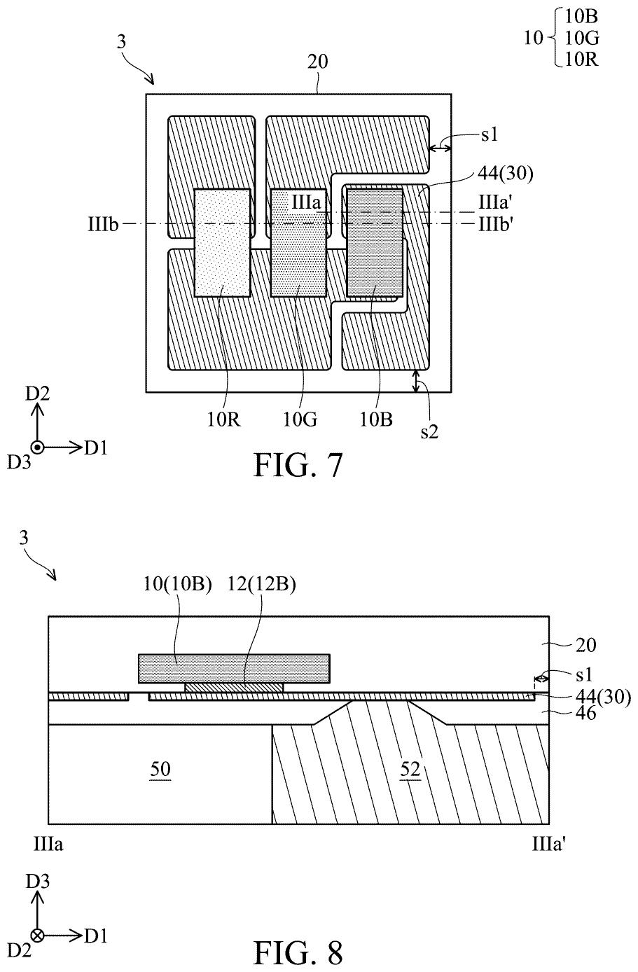

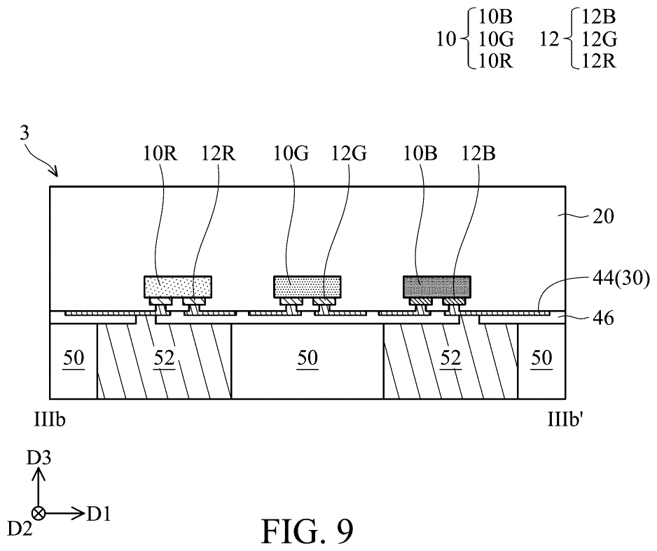

Referring to FIG. 7, it is a schematic top view of a packaging structure 3 according to some embodiments of the present disclosure. Referring to FIG. 8 and FIG. 9, they are schematic cross-sectional views of the packaging structure 3 according to some embodiments of the present disclosure. Wherein, FIG. 8 shows a schematic cross-sectional view taken along line segment IIIa-IIIa′ in FIG. 7, and FIG. 9 shows a schematic cross-sectional view taken along line segment IIIb-IIIb′ in FIG. 7.

As shown in FIGS. 7 and 8, in some embodiments, a patterned metal layer may be formed on the cover layer 20, wherein the patterned metal layer may serve as both the redistribution layer 44 and the photodegradation prevention layer 30. Accordingly, the process of forming the packaging structure 3 can be simplified, and the photodegradation prevention layer 30 and the redistribution layer 44 can be formed at the same time.

As shown in FIG. 7, in some embodiments, the photodegradation prevention layer 30 may be directly connected to the redistribution layer 44. In some embodiments, the redistribution layer 44 may substantially function as the photodegradation prevention layer 30. Therefore, in a top view, an area of the redistribution layer 44 (the photodegradation prevention layer 30) may account for at least 50% of the area of the cover layer 20. In some embodiments, the area of the cover layer 20 may be substantially equal to the area of the packaging structure 3. In some embodiments, the area of the redistribution layer 44 (the photodegradation prevention layer 30) may account for at least 50% of the area of the packaging structure 3. Accordingly, the bonding margin between the redistribution layer 44 and the light-emitting element 10 can be improved. In addition, the bonding margin between the metal pillars 52 and the redistribution layer 44 and/or the bonding area between the metal pillars 52 and the redistribution layer 44 may be increased. Therefore, the reliability of the packaging structure 3 is improved.

As shown in FIGS. 8 and 9, in some embodiments, the photodegradation prevention layer 30, that is, the redistribution layer 44, may be in direct contact with the cover layer 20. In some embodiments, the photodegradation prevention layer 30 may cover the bottom surfaces of the plurality of light-emitting elements 10. In some embodiments, the projection range of the light-emitting elements 10 on the cover layer 20 may be located within the projection range of the photodegradation prevention layer 30 on the cover layer 20. Accordingly, since the photodegradation prevention layer 30 can cover the bottom surfaces of the plurality of light-emitting elements 10, the photodegradation prevention layer 30 can effectively block the light emitted by the light-emitting element 10 from damaging other elements in the packaging structure 3. Specifically, it is possible to prevent the light emitted from the light-emitting element 10 from being reflected or scattered and irradiating other elements, thereby preventing the other elements from being degraded. In some embodiments, the intermediate layer 42 may be omitted in the packaging structure 3 to reduce the overall thickness of the packaging structure 3 and/or simplify the process. In some embodiments, a portion of the dielectric layer 46 may be exposed from the photodegradation prevention layer 30 and the redistribution layer 44. That is, the portion of the dielectric layer 46 may be exposed from the distance s1 between the edge of the photodegradation prevention layer 30 (the redistribution layer 44) and the edge of the cover layer 20.

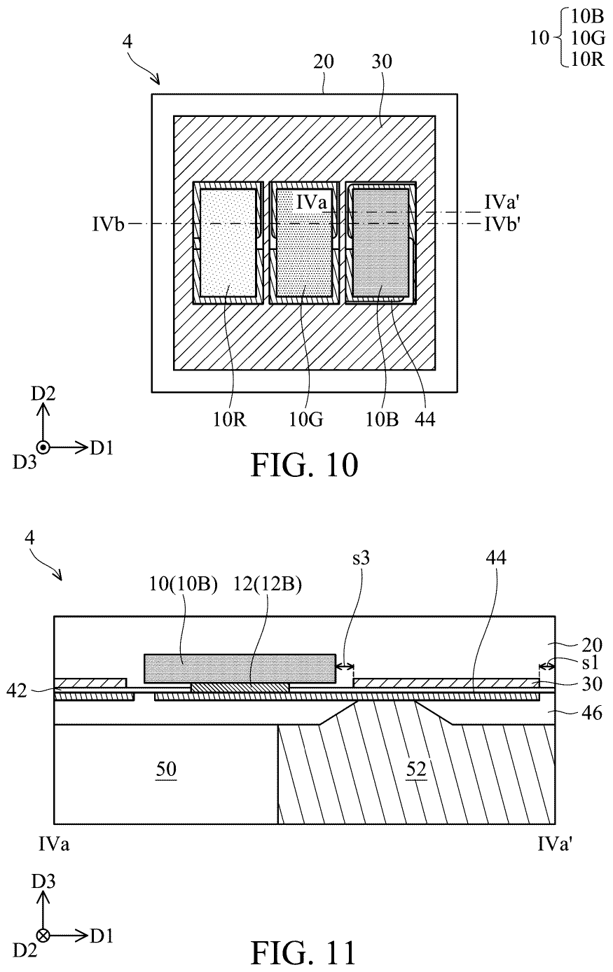

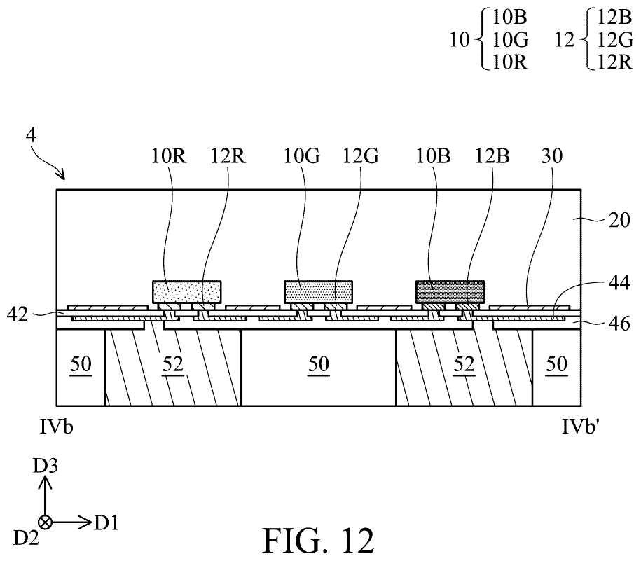

Referring to FIG. 10, it is a schematic top view of a packaging structure 4 according to some embodiments of the present disclosure. Referring to FIGS. 11 and 12, they are schematic cross-sectional views of the packaging structure 4 according to some embodiments of the present disclosure. Wherein, FIG. 11 is a schematic cross-sectional view taken along line segment IVa-IVa′ in FIG. 10, and FIG. 12 is a schematic cross-sectional view taken along line segment IVb-IVb′ in FIG. 10.

As shown in FIG. 10, in some embodiments, a patterned metal layer may be formed on the cover layer 20, wherein the patterned metal layer may serve as the photodegradation prevention layer 30. Next, another patterned metal layer may be formed on the photodegradation prevention layer 30, wherein the other patterned metal layer may serve as the redistribution layer 44. Accordingly, the photodegradation prevention layer 30 and the redistribution layer 44 can be formed at the same time.

As shown in FIG. 10, in some embodiments, in a top view, the area of the redistribution layer 44 may accounts for at least 50% of the area of the cover layer 20. For example, the area of the redistribution layer 44 may be 50%, 55%, 60%, 65%, 70%, 75%, 80%, 85%, 90%, 95%, 97%, 99%, 100% of the area of the cover layer 20, or any value or any range of values between the aforementioned values, but the present disclosure is not limited thereto. In some embodiments, the area of the cover layer 20 may be substantially equal to the area of the top view of the packaging structure 4. In some embodiments, the area of the redistribution layer 44 may account for at least 50% of the area of the top view of the packaging structure 4. Accordingly, since the redistribution layer 44 has a sufficient top-view area, the redistribution layer 44 can effectively prevent the light emitted from the light-emitting element 10 in the packaging structure 4 from damaging other elements in the packaging structure 4.

In some embodiments, the area of the redistribution layer 44 may be larger than the area of the photodegradation prevention layer 30. In some embodiments, the difference between the area of the redistribution layer 44 and the area of the photodegradation prevention layer 30 may be greater than 5%, 10%, 15%, 20%, 25%, 30%, 35%, 40%, 44% of the area of the cover layer 20, or any value or any range of values between the aforementioned values, but the present disclosure is not limited thereto. For example, when the area of the cover layer 20 may be 100%, the area of the photodegradation prevention layer 30 may be at least 50%, and the area of the redistribution layer 44 may be at least 55%. Accordingly, by providing the photodegradation prevention layer 30 and the redistribution layer 44, it is possible to effectively prevent the light emitted by the light-emitting element 10 in the packaging structure 4 from damaging other elements in the packaging structure 4.

As shown in FIGS. 11 and 12, in some embodiments, the photodegradation prevention layer 30 may be in direct contact with the cover layer 20. In some embodiments, the bottom surface of the photodegradation prevention layer 30 may be flush with the bottom surface of the cover layer 20. As shown in FIGS. 11 and 12, in some embodiments, the photodegradation prevention layer 30 may be disposed on the redistribution layer 44, and the redistribution layer 44 may be disposed between the photodegradation prevention layer 30 and the dielectric layer 46.

As shown in FIG. 11 and FIG. 12, in some embodiments, the redistribution layer 44 may cover the bottom surfaces of the plurality of light-emitting elements 10. In some embodiments, the projection range of the light-emitting element 10 on the cover layer 20 may be located within the projection range of the redistribution layer 44 on the cover layer 20. Accordingly, since the redistribution layer 44 can cover the bottom surfaces of the plurality of light-emitting elements 10, both the redistribution layer 44 and the photodegradation prevention layer 30 can effectively block the light emitted by the light-emitting element 10 from damaging other elements in the packaging structure 4. Specifically, it is possible to prevent the light emitted from the light-emitting element 10 from being reflected or scattered and irradiating other elements, thereby preventing the other elements from being degraded.

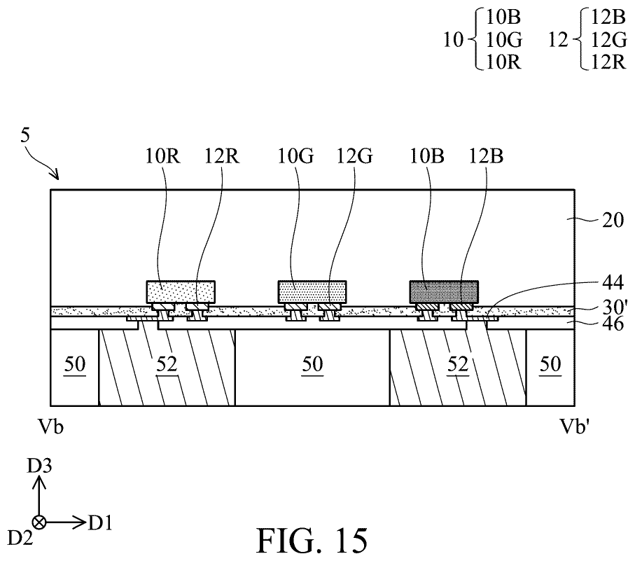

Referring to FIG. 13, it is a schematic top view of a packaging structure 5 according to some embodiments of the present disclosure. Referring to FIGS. 14 and 15, they are schematic cross-sectional views of the packaging structure 5 according to some embodiments of the present disclosure. Wherein, FIG. 14 shows a schematic cross-sectional view taken along the line segment Va-Va′ in FIG. 13, and FIG. 15 shows a schematic cross-sectional view taken along the line segment Vb-Vb′ in FIG. 13.

As shown in FIG. 13, in some embodiments, a Bragg reflector may be formed on the cover layer 20, wherein the Bragg reflector may serve as a photodegradation prevention layer 30′. In some embodiments, in the first direction D1, an edge 30′E1 of the photodegradation prevention layer 30′ may be flush with the edge 20E1 of the cover layer 20. In some embodiments, in the first direction D1, an edge 30′E3 of the photodegradation prevention layer 30′ may be flush with the edge 20E3 of the cover layer 20. In some embodiments, in the second direction D2, an edge 30′E2 of the photodegradation prevention layer 30′ may be flush with the edge 20E2 of the cover layer 20. In some embodiments, in the second direction D2, an edge 30′E4 of the photodegradation prevention layer 30′ may be flush with the edge 20E4 of the cover layer 20. Accordingly, an area of the photodegradation prevention layer 30′ can be increased to enhance the blocking effect of the photodegradation prevention layer 30′ on the light emitted by the light-emitting element 10.

As shown in FIGS. 14 and 15, in some embodiments, a top surface of the photodegradation prevention layer 30′ may be in direct contact with the bottom surface of the cover layer 20. In some embodiments, the photodegradation prevention layer 30′ may include the Bragg reflector, and the photodegradation prevention layer 30′ may be disposed on the redistribution layer 44. In some embodiments, the photodegradation prevention layer 30′ may cover the bottom surfaces of the plurality of light-emitting elements 10. In some embodiments, the projection range of the light-emitting element 10 on the cover layer 20 may be located within the projection range of the photodegradation prevention layer 30′ on the cover layer 20. Accordingly, since the photodegradation prevention layer 30′ can cover the bottom surfaces of the plurality of light-emitting elements 10, the photodegradation prevention layer 30′ can effectively block the light emitted by the light-emitting element 10 from damaging other elements in the packaging structure 5. Specifically, it is possible to prevent the light emitted from the light-emitting element 10 from being reflected or scattered and irradiating other elements, thereby preventing the other elements from being degraded. In some embodiments, the photodegradation prevention layer 30′ may cover a portion of the top surface of the redistribution layer 44, and the light-emitting element 10 may be disposed on the remaining portion of the top surface of the redistribution layer 44, wherein the remaining portion is exposed by the photodegradation prevention layer 30′.

In some embodiments, the packaging structure of the present disclosure may be applied to applications requiring high light-emitting efficiency and high brightness.

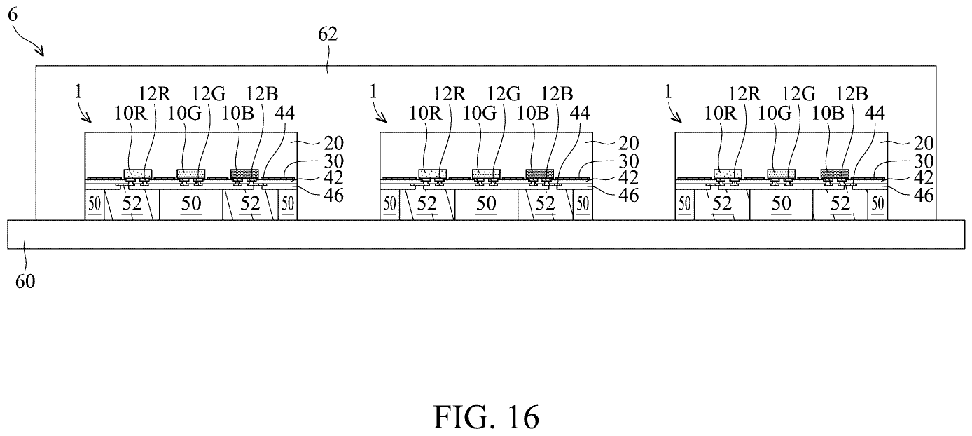

Referring to FIG. 16, it is a schematic cross-sectional view of a display device 6 according to some embodiments of the present disclosure. In some embodiments, the display device 6 may include one or more of the packaging structures 1 to 5 or any combination thereof. The packaging structures 1 to 5 can be used as a pixel unit and applied in the display device 6. In some embodiments, the display device 6 may further include an additional conductive layer, an additional insulating layer, an additional element, or a combination thereof, but the present disclosure is not limited thereto. In some embodiments, the number of packaging structures in the display device 6 may be 1 to 10000. For the convenience of description, FIG. 16 shows that the display device 6 includes three packaging structures 1, but the present disclosure is not limited thereto. In some embodiments, the display device 6 may include a circuit board 60, and the packaging structure 1 may be disposed on the circuit board 60. For example, the circuit board 60 may be a printed circuit board (PCB). In some embodiments, the packaging structure 1 and the circuit board 60 may be electrically connected by a bonding material. In some embodiments, the display device 6 may include a packaging material 62, and the packaging material 62 may cover a top surface and a side surface of the packaging structure 1 and a top surface of the circuit board 60.

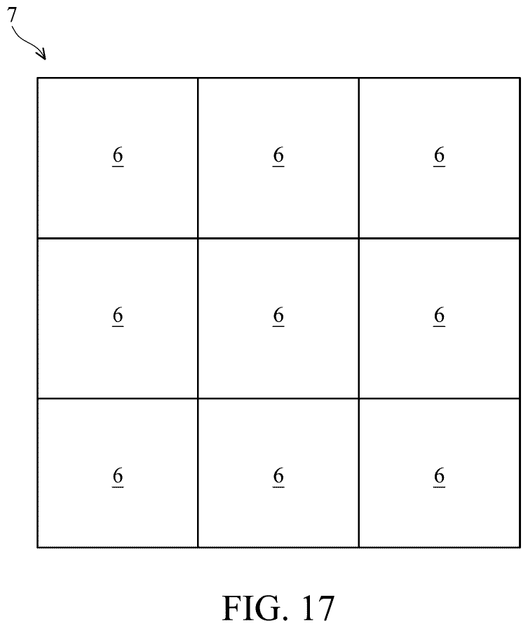

Referring to FIG. 17, it is a schematic top view of a spliced display device 7 according to some embodiments of the present disclosure. In some embodiments, the spliced display device 7 may include multiple display devices 6. In some embodiments, the number of display devices 6 in the spliced display device 7 may be 1 to 10000. For ease of description, FIG. 17 shows that the spliced display device 7 includes nine display devices 6, but the present disclosure is not limited thereto.

Accordingly, the present disclosure improves the light-emitting efficiency of the packaging structure, improves the bonding reliability, and/or avoids electrical failure by providing the photodegradation prevention layer. For example, the problem of the dielectric layer and/or the intermediate layer being degraded after being irradiated by light from the light-emitting element can be avoided. Furthermore, since the reliability of the intermediate layer can be improved, the bonding reliability between the intermediate layer and the cover layer can be improved accordingly. Furthermore, since the reliability of the intermediate layer itself and the bonding reliability between the intermediate layer and the cover layer can be improved, external moisture and impurities can be prevented from entering the packaging structure, thereby improving the light-emitting efficiency, electrical stability, and/or reliability of the packaging structure.

The features among the various embodiments may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A packaging structure comprising:
a dielectric layer;
a redistribution layer disposed on the dielectric layer;
a plurality of light-emitting elements disposed on the redistribution layer and electrically connected to the redistribution layer;
a photodegradation prevention layer disposed on the dielectric layer and surrounding the plurality of light-emitting elements; and
a cover layer disposed on the plurality of light-emitting elements and the photodegradation prevention layer,
wherein an area of the photodegradation prevention layer accounts for at least 50% of an area of the cover layer.

2. The packaging structure as claimed in claim 1, wherein each of the plurality of light-emitting elements comprises a bonding pad and the photodegradation prevention layer surrounds the bonding pad.

3. The packaging structure as claimed in claim 1, wherein a distance between an edge of the photodegradation prevention layer and an edge of the cover layer is less than 20 um.

4. The packaging structure as claimed in claim 1, wherein an edge of the photodegradation prevention layer is flush with an edge of the cover layer.

5. The packaging structure as claimed in claim 1, wherein the photodegradation prevention layer is in direct contact with the cover layer.

6. The packaging structure as claimed in claim 1, wherein the photodegradation prevention layer comprises a metal.

7. The packaging structure as claimed in claim 6, wherein the redistribution layer is in direct contact with the cover layer.

8. The packaging structure as claimed in claim 7, wherein a top surface of the photodegradation prevention layer is flush with a top surface of the redistribution layer.

9. The packaging structure as claimed in claim 7, wherein the photodegradation prevention layer surrounds the redistribution layer and is separated from the redistribution layer by a distance.

10. The packaging structure as claimed in claim 7, wherein the photodegradation prevention layer and the redistribution layer are formed by the same process step.

11. The packaging structure as claimed in claim 7, wherein the photodegradation prevention layer is disposed on the redistribution layer, and the redistribution layer is disposed between the photodegradation prevention layer and the dielectric layer.

12. The packaging structure as claimed in claim 11, wherein an area of the redistribution layer accounts for at least 50% of an area of the cover layer.

13. The packaging structure as claimed in claim 11, wherein the photodegradation prevention layer is separated from the plurality of light-emitting elements by a distance, and the distance is less than or equal to 10 um.

14. The packaging structure as claimed in claim 6, further comprising:
an intermediate layer disposed on the redistribution layer,
wherein, the photodegradation prevention layer is disposed on the intermediate layer.

15. The packaging structure as claimed in claim 14, wherein the redistribution layer is separated from the cover layer by a distance.

16. The packaging structure as claimed in claim 14, wherein the photodegradation prevention layer is separated from the plurality of light-emitting elements by a distance, and the distance is less than or equal to 10 um.

17. The packaging structure as claimed in claim 1, wherein the photodegradation prevention layer is disposed on the redistribution layer, and the photodegradation prevention layer comprises a Bragg reflector.

18. The packaging structure as claimed in claim 1, wherein the photodegradation prevention layer covers a bottom surface of the plurality of light-emitting elements.

19. The packaging structure as claimed in claim 1, further comprising:
a filling material layer, wherein the dielectric layer is disposed between the redistribution layer and the filling material layer; and
a metal pillar disposed in the filling material layer and electrically connected to the redistribution layer.

20. A packaging structure comprising:
a dielectric layer;
a redistribution layer disposed on the dielectric layer;
a plurality of light-emitting elements disposed on the redistribution layer and electrically connected to the redistribution layer; and
a cover layer disposed on the plurality of light-emitting elements and the photodegradation prevention layer,
wherein an area of the redistribution layer accounts for at least 50% of an area of the cover layer.
